(19) United States
(12) Patent Application Publication
(10) Pub. No.: US 2015/0021665 A1
(43) Pub. Date: Jan. 22, 2015

(54) TRANSISTOR HAVING BACK-BARRIER LAYER AND METHOD OF MAKING THE SAME

(71) Applicant: TAIWAN SEMICONDUCTOR MANUFACTURING COMPANY, LTD., Hsinchu (TW)

(72) Inventors: Chi-Ming CHEN, Zhubei City (TW); Po-Chun LIU, Hsinchu City (TW); Chen-Hao CHIANG, Jhongli City (TW); Ming-Chang CHING, Zhubei City (TW); Ming-Chyi LIU, Hsinchu City (TW); Chung-Yi YU, Hsinchu (TW)

(73) Assignee: TAIWAN SEMICONDUCTOR MANUFACTURING COMPANY, LTD., Hsinchu (TW)

(21) Appl. No.: 13/944,584

(22) Filed: Jul. 17, 2013

(51) Int. Cl. H01L 29/778; H01L 29/66

(52) U.S. Cl. CPC H01L 29/778; H01L 29/66431
USPC 257/194; 438/172

(57) ABSTRACT

A transistor includes a substrate, a channel layer over the substrate, a back-barrier layer over the channel layer, and an active layer over the back-barrier layer. The back-barrier layer has a band gap discontinuity with the channel layer. The band gap of the active layer is less than the band gap of the back-barrier layer. A two dimensional electron gas (2-DEG) is formed in the channel layer adjacent an interface between the channel layer and the back-barrier layer.

### RELATED APPLICATIONS

The instant application is related to the following U.S. Patent Applications:
U.S. Patent Application titled “TRANSISTOR HAVING PARTIALLY OR WHOLLY REPLACED SUBSTRATE AND METHOD OF MAKING THE SAME,” attorney docket No. TSMC2013-0480 (T5057-898);
U.S. Patent Application titled “TRANSISTOR HAVING HIGH BREAKDOWN VOLTAGE AND METHOD OF MAKING THE SAME,” attorney docket No. TSMC2013-0481 (T5057-897);
U.S. Patent Application titled “TRANSISTOR HAVING DOPED SUBSTRATE AND METHOD OF MAKING THE SAME,” attorney docket No. TSMC2013-0484 (T5057-899);
U.S. Patent Application titled “TRANSISTOR HAVING A BACK-BARRIER LAYER AND METHOD OF MAKING THE SAME,” attorney docket No. TSMC2013-0485 (T5057-896);
U.S. Patent Application titled “TRANSISTOR HAVING OHMIC CONTACT BY GRADIENT LAYER AND METHOD OF MAKING SAME” attorney docket no. TSMC2013-0530 (T5057-904);
U.S. Patent Application titled “TRANSISTOR HAVING AN OHMIC CONTACT BY SCREEN LAYER AND METHOD OF MAKING THE SAME” attorney docket no. TSMC2013-0531 (T5057-902);
U.S. Patent Application titled “TRANSISTOR HAVING METAL DIFFUSION BARRIER AND METHOD OF MAKING THE SAME” attorney docket no. TSMC2013-0615 (T5057-915); and
U.S. Patent Application titled “SEMICONDUCTOR DEVICE, HIGH ELECTRON MOBILITY TRANSISTOR (E-HEMT) AND METHOD OF MANUFACTURING,” attorney docket no. TSMC2013-0482 (T5057-895).

The entire contents of the above-referenced applications are incorporated by reference herein.

### BACKGROUND

In semiconductor technology, Group III-Group V (or III-V) semiconductor compounds are used to form various integrated circuit devices, such as high power field-effect transistors, high frequency transistors, high electron mobility transistors (HEMTs), or metal-insulator-semiconductor field-effect transistors (MISFETs). A HEMT is a field effect transistor incorporating a junction between two materials with different band gaps (i.e., a heterojunction) as the channel instead of a doped region, as is generally the case for metal oxide semiconductor field effect transistors (MOSFETs). In contrast with MOSFETs, HEMTs have a number of attractive properties including high electron mobility and the ability to transmit signals at high frequencies, etc.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. It is emphasized that, in accordance with standard practice in the industry various features may not be drawn to scale and are used for illustration purposes only. In fact, the dimensions of the various features in the drawings may be arbitrarily increased or reduced for clarity of discussion.

FIG. 1 is a cross-sectional view of a high electron mobility transistor (HEMT) having a back-barrier layer in accordance with one or more embodiments;

FIG. 2A is a band diagram of an HEMT having a back-barrier layer in accordance with one or more embodiments;

FIG. 2B is a band diagram of an HEMT without a back-barrier layer;

FIG. 3 is a flow chart of a method of making an HEMT having a back-barrier layer in accordance with one or more embodiments;

FIGS. 4A-4D are cross-sectional views of a HEMT having a back-barrier layer at various stages of production in accordance with one or more embodiments;

FIG. 5 is a cross-sectional view of an enhanced HEMT (E-HEMT) in accordance with one or more embodiments;

FIG. 6 is a cross-sectional view of a depletion metal-insulator-semiconductor field-effect transistor (D-MISFET) in accordance with one or more embodiments; and

FIG. 7 is a cross-sectional view of an enhanced metal-insulator-semiconductor field-effect transistor (E-MISFET) in accordance with one or more embodiments.

### DETAILED DESCRIPTION

The following disclosure provides many different embodiments, or examples, for implementing different features of the invention. Specific examples of components and arrangements are described below to simplify the present disclosure. These are examples and are not intended to be limiting.

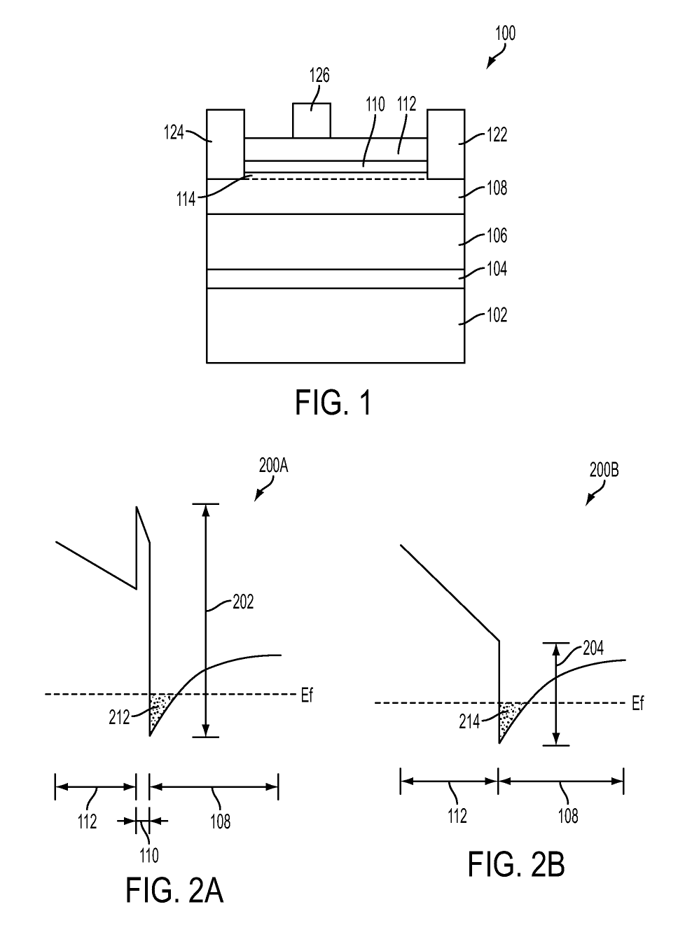

FIG. 1 is a cross-sectional view of a high electron mobility transistor (HEMT) 100 having a back-barrier layer 110 in accordance with one or more embodiments. HEMT 100 includes a substrate 102. A nucleation layer 104 is over substrate 102. In some embodiments, nucleation layer 104 includes multiple layers, such as seed layers and/or graded layers. HEMT 100 further has a buffer layer 106 over nucleation layer 104 and a channel 108 over the buffer layer 106. Back-barrier layer 110 is over channel layer 108. An active layer 112 is over the back-barrier layer 110. Due to a band gap discontinuity between the channel layer 108 and a combination of active layer 112 and back-barrier layer 110, a two dimension electron gas (2-DEG) 114 is formed in the channel layer 108 near an interface with the back-barrier layer 110. Drain or source electrodes 122 and 124 are over the channel layer 108, and a gate electrode 126 is over active layer 112 between the drain or source electrodes 122 and 124.

Substrate 102 acts as a support for HEMT 100. In some embodiments, substrate 102 is a silicon substrate. In some embodiments, substrate 102 includes silicon carbide (SiC), sapphire, or another suitable substrate material. In some embodiments, substrate 102 is a silicon substrate having a (111) lattice structure.

Nucleation layer 104 helps to compensate for a mismatch in lattice structures between substrate 102 and buffer layer 106. In some embodiments, nucleation layer 104 includes multiple layers. In some embodiments, nucleation layer 104 includes a same material formed at different temperatures. In some embodiments, nucleation layer 104 includes a step-wise change in lattice structure. In some embodiments, nucleation layer 104 includes a continuous change in lattice structure. In some embodiments, nucleation layer 104 is formed by epitaxially growing the nucleation layer on substrate 102.

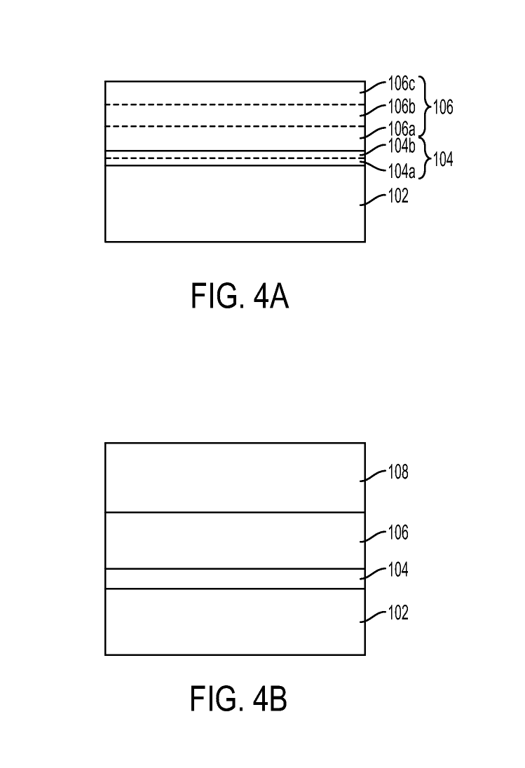

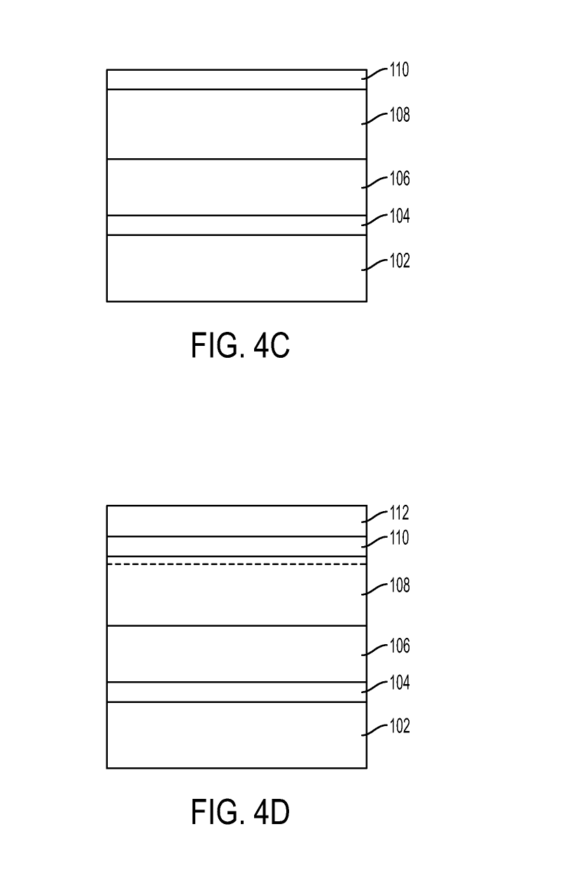

In at least one example, nucleation layer 104 comprises a first layer of aluminum nitride (AlN) (e.g., layer 104a in FIG. 4A) and a second layer of AlN (e.g., layer 104b in FIG. 4A) over the first layer of AlN. The first layer of AlN is formed at a low temperature, ranging from about 900° C. to about 1000° C., and has a thickness ranging from about 20 nanometers (nm) to about 80 nm. If the thickness of the first layer of AlN is too small, subsequent layers formed on the first layer of AlN will experience a high stress at the interface with the first AlN layer due to lattice mismatch increasing a risk of layer separation. If the thickness of the first layer of AlN is too great, the material is wasted and production costs increase. The second layer of AlN is formed at a high temperature, ranging from about 1000° C. to about 1300° C., and has a thickness ranging from about 50 nanometers (nm) to about 200 nm. The higher temperature provides a different lattice structure in the second AlN layer in comparison with the first AlN layer. The lattice structure in the second AlN layer is more different from a lattice structure of substrate 102 than the first AlN layer. If the thickness of the second layer of AlN is too small, subsequent layers formed on the second layer of AlN will experience a high stress at the interface with the second layer of AlN due to lattice mismatch increasing the risk of layer separation. If the thickness of the second layer of AlN is too great, the material is wasted and production costs increase.

In at least one embodiment, the buffer layer 106 includes a graded layer. The graded layer includes aluminum gallium nitride (AlₓGa₁₋ₓN) and is formed over the second AlN layer. X is the aluminum content ratio in the graded layer. In some embodiments, the graded layer includes multiple layers each having a decreased ratio x (from a layer closer to the second AlN layer to a layer closer to channel layer 108, or from the bottom to the top portions of the graded layer). In at least one embodiment, the graded aluminum gallium nitride layer has three layers whose ratios x are 0.9˜0.7, 0.6˜0.4, and 0.3˜0.15, from the bottom to the top. In some embodiments, instead of having multiple layers, the graded layer has a continuous gradient of the x value. In some embodiments, x ranges from about 0.9 to about 0.15. In some embodiments, graded layer has a thickness ranging from about 50 nm to about 250 nm. If the graded layer is too thin, channel layer 108 will have a high stress at an interface with nucleation layer 104 and increase the risk of separation between the buffer layer and the nucleation layer. If the graded layer is too thick, material is wasted and production costs increase. In some embodiments, the graded layer is formed at a temperature ranging from about 1000° C. to about 1200° C.

In some embodiments, nucleation layer 104 is omitted, and thus buffer layer 106 is directly on substrate 102.

Channel layer 108 is used to help form a conductive path for selectively connecting electrodes 122 and 124. In some embodiments, channel layer 108 includes GaN. In some embodiments, channel layer 108 is an un-doped layer or has a p-type dopant concentration of equal to or less than 1×10¹⁷ ions/cm³. In some embodiments, channel layer 108 is an undoped layer or an unintentionally doped layer. In some embodiments, channel layer 108 has a thickness ranging from about 0.5 μm to about 5 μm. If a thickness of channel layer 108 is too thin, channel layer 108 will not provide sufficient charge carriers to allow HEMT 100 to function properly. If the thickness of channel layer 108 is too great, material is wasted and production costs increase. In some embodiments, channel layer 108 is formed by an epitaxial process. In some embodiments, channel layer 108 is formed at a temperature ranging from about 1000° C. to about 1200° C.

Back-barrier layer 110 has a high band gap with respect to active layer 112 and a band gap discontinuity with respect to channel layer 108 and active layer 112. The band gap discontinuity acts to reduce a depth of 2-DEG 114, and thus to increases carrier density and carrier mobility of the 2-DEG 114. As a result, a turned-on resistance between electrodes 122 and 124 is reduced.

FIG. 2A is a band diagram 200A of an HEMT having a back-barrier layer in accordance with one or more embodiments. FIG. 2B is a band diagram 200B of an HEMT without a back-barrier layer. Band diagram 200A and 200B indicate electron energy levels versus a depth into the HEMT in comparison with Fermi Level Ef. Band diagram 200A indicates a band gap difference 202 of an HEMT including a back-barrier layer, e.g., back-barrier layer 110 between active layer 112 and channel layer 108. Band gap difference 202 indicates a discontinuity at an interface of channel layer 108 and the back-barrier layer 110. Also, a 2-DEG 212 (indicated by the dotted region below the Fermi Level Ef) is formed in channel layer 108 near heterojunction between back-barrier layer 110 and channel layer 108. Band diagram 200B indicates a band gap difference 204 of an HEMT without a back-barrier layer, e.g., no back-barrier layer 110 between active layer 112 and channel layer 108. Band gap difference 204 indicates a discontinuity at an interface of channel layer 108 and the active layer 110 (when back-barrier layer 110 is omitted). Also, a 2-DEG 214 (indicated by the dotted region below the Fermi Level Ef) is formed in channel layer 108 near heterojunction between active layer 112 and channel layer 108.

As depicted in FIGS. 2A and 2B, the effect of the insertion of back-barrier layer 110 is to cause a band gap difference 202 greater than band gap difference 204. The greater band gap difference 202 helps to cause a depth of 2-DEG 212 less than a depth of 2-DEG 214. Thus, charge carriers in 2-DEG 212 tend to have a higher carrier density and a higher carrier mobility than those of 2-DEG 214. In some embodiments, the band gap difference 202 is at least 0.5 electron volt (eV) greater than the band gap difference 204. In some embodiments, the band gap difference 202 is about 1.8 eV greater than the band gap difference 204.

Returning to FIG. 1, in some embodiments, back-barrier layer 110 is formed by an epitaxial process. In some embodiments, back-barrier layer 110 is formed at a temperature ranging from about 1000° C. to about 1200° C.

In some embodiments, back-barrier layer 110 includes AlN. In some embodiments, the back-barrier layer has a thickness ranging from about 1 angstrom (Å) to about 10 Å. In some embodiments, the back-barrier layer 110 has a thickness ranging from about 1 Å to about 5 Å. Although as the back-barrier layer 110 becomes thicker, the less depth of the resulting 2-DEG is, the increased thickness also causes increased contact resistance between the electrodes 122 and 124. Therefore, too large or too small the thickness of the back-barrier layer 110 increases the turned-on resistance between electrodes 122 and 124.

Active layer 112, used in conjunction with the back-barrier layer 110, is usable to provide the band gap discontinuity with the channel layer to form 2-DEG 114. In some embodiments, active layer 112 includes AlN. In some embodiments, active layer 112 includes a mixed structure, e.g., AlₓGa₁₋ₓN, where x ranges from about 0.1 to 0.3. In some embodiments, active layer 112 includes both AlN and the mixed structure. In some embodiments, active layer 112 has a thickness ranging from about 10 nm to about 40 nm. In some embodiments where active layer 112 includes an AlN layer and a mixed structure layer, a thickness of the AlN layer ranges from about 0.5 nm to about 1.5 nm and a thickness of the mixed structure layer ranges from about 10 nm to about 40 nm. If active layer 112 is too thick, selectively controlling the conductivity of the channel layer is difficult. If active layer 112 is too thin, an insufficient amount of electrons are available for 2-DEG 114. In some embodiments, active layer 112 is formed using an epitaxial process. In some embodiments, active layer 112 is formed at a temperature ranging from about 1000° C. to about 1200° C.

In some embodiments, a band gap of the back-barrier layer 110 is at least 0.5 eV greater than a band gap of the active layer 112. In some embodiments, a band gap of the back-barrier layer 110 is about 1.8 eV greater than a band gap of the active layer 112.

2-DEG 114 acts as the channel for providing conductivity between electrodes 122 and 124. Electrons from a piezoelectric effect in active layer 112 drop into the channel layer, and thus create a thin layer of highly mobile conducting electrons in the channel layer.

In at least one embodiments, electrodes 122 and 124 act as a drain electrode and a source electrode for HEMT 100 for transferring a signal into or out of the HEMT. Gate electrode 126 helps to modulate conductivity of 2-DEG 114 for transferring the signal between electrodes 122 and 124.

HEMT 100 is normally conductive meaning that a positive voltage applied to gate 126 will reduce the conductivity between electrodes 122 and 124 along 2-DEG 114. In some applications, HEMT 100 is also known as a depletion mode HEMT.

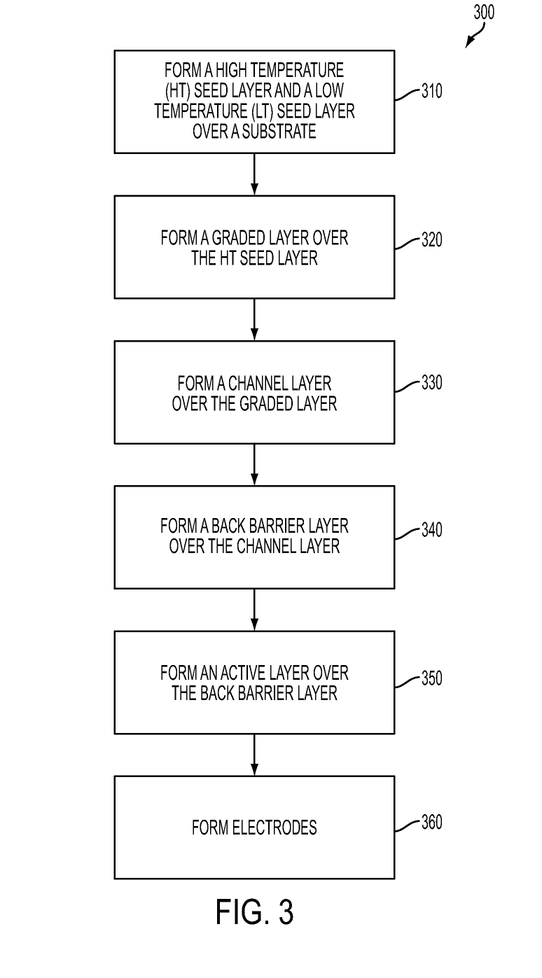

FIG. 3 is a flow chart of a method 300 of making an HEMT having a back-barrier layer in accordance with one or more embodiments. Method 300 begins with operation 310 in which a low temperature (LT) seed layer and a high temperature (HT) seed layer are formed on a substrate, e.g., substrate 102. The LT seed layer is formed on the substrate and the HT seed layer is formed on the LT seed layer.

In some embodiments, LT seed layer and HT seed layer include AlN. In some embodiments, the formation of LT seed layer and HT seed layer is performed by an epitaxial growth process. In some embodiments, the epitaxial growth process includes a metal-organic chemical vapor deposition (MOCVD) process, a molecular beam epitaxy (MBE) process, a hydride vapor phase epitaxy (HVPE) process or another suitable epitaxial process. In some embodiments, the MOCVD process is performed using aluminum-containing precursor and nitrogen-containing precursor. In some embodiments, the aluminum-containing precursor includes trimethylaluminium (TMA), triethylaluminium (TEA), or other suitable chemical. In some embodiments, the nitrogen-containing precursor includes ammonia, tertiarybutylamine (TBAm), phenyl hydrazine, or other suitable chemical. In some embodiments, the LT seed layer or the HT seed layer includes a material other than AlN. In some embodiments, the HT seed layer has a thickness ranging from about 50 nm to about 200 nm. In some embodiments, the HT seed layer is formed at a temperature ranging from about 1000° C. to about 1300° C. In some embodiments, the LT seed layer had a thickness ranging from about 20 nm to about 80 nm. In some embodiments, the LT seed layer is formed at a temperature ranging from about 900° C. to about 1000° C.

Method 300 continues with operation 320 in which a graded layer is formed on the HT seed layer. In some embodiments, the graded layer includes an aluminum-gallium nitride (AlₓGa₁₋ₓN) layer. In some embodiments, the graded aluminum gallium nitride layer has two or more aluminum-gallium nitride layers each having a different ratio x decreased from the bottom to the top. In some embodiments, the graded aluminum gallium nitride layer includes three aluminum-gallium nitride layers (e.g., layers 106a, 106b, and 106c in FIG. 4A). In some embodiments, layer 106a has a thickness ranging from about 50 nm to about 200 nm. In some embodiments, layer 106b has a thickness ranging from about 150 nm to about 250 nm. In some embodiments, layer 106c has a thickness ranging from about 350 nm to about 600 nm.

In some embodiments, each of the two or more aluminum-gallium nitride layers is formed by performing an epitaxial process. In some embodiments, the epitaxial process includes a MOCVD process, a MBE process, a HVPE process or another suitable epitaxial process. In some embodiments, the MOCVD process uses an aluminum-containing precursor, a gallium-containing precursor, and a nitrogen-containing precursor. In some embodiments, the aluminum-containing precursor includes TMA, TEA, or other suitable chemical. In some embodiments, the gallium-containing precursor includes trimethylgallium (TMG), triethylgallium (TEG), or other suitable chemical. In some embodiments, the nitrogen-containing precursor includes ammonia, TBAm, phenyl hydrazine, or other suitable chemical. In some embodiments, the graded aluminum gallium nitride layer has a continuous gradient of the ratio x gradually decreased from the bottom to the top. In some embodiments, x ranges from about 0.15 to about 0.9. In some embodiments, the graded layer is formed at a temperature ranging from about 1000° C. to about 1200° C.

FIG. 4A is a cross-sectional view of a HEMT following operation 410 in accordance with one or more embodiments. The HEMT includes substrate 102, nucleation layer 104 over the substrate, and buffer layer 106 over the nucleation layer 104. Nucleation layer 104 includes an LT seed layer 104a over the substrate 102 and an HT seed layer 104b over the LT seed layer. Buffer layer 106 includes graded layers 106a, 106b, and 106c stacked one over another.

Returning to FIG. 3, in operation 330 a channel layer is formed over the buffer layer. In some embodiments, the channel layer includes p-type dopants. In some embodiments, the channel layer includes GaN, and the P-type doping is implemented by using dopants including carbon, iron, magnesium, zinc or other suitable p-type dopants. In some embodiments, the channel layer is formed by performing an epitaxial process. In some embodiments, the epitaxial process includes a MOCVD process, a MBE process, a HVPE process or another suitable epitaxial process. In some embodiments, the channel layer has a thickness ranging from about 0.5 μm to about 5 μm. In some embodiments, the dopant concentration in the channel layer is equal to or less than about 1×10¹⁷ ions/cm³. In some embodiments, the channel layer is an undoped layer or an unintentionally doped layer. In some embodiments, the channel layer is formed at a temperature ranging from about 1000° C. to about 1200° C.

FIG. 4B is a cross-sectional view of a HEMT following operation 330 in accordance with one or more embodiments. The HEMT includes channel layer 108 over buffer layer 106.

Returning to FIG. 3, in operation 340 a back-barrier layer is formed over the channel layer. In some embodiments, the back-barrier layer includes AlN, AlₓGa₁₋ₓN, In_{y}Al_{1-y}N, combinations thereof or other suitable materials. In some embodiments, the back-barrier layer is formed by performing an epitaxial process. In some embodiments, the epitaxial process includes a MOCVD process, a MBE process, a HVPE process or another suitable epitaxial process. In some embodiments, the back-barrier layer has a thickness ranging from about 1 Å to about 10 Å. In some embodiments, the back-barrier layer has a thickness ranging from about 1 Å to about 5 Å. In some embodiments, the back-barrier layer is formed at a temperature ranging from about 1000° C. to about 1200° C.

FIG. 4C is a cross-sectional view of a HEMT following operation 340 in accordance with one or more embodiments. The HEMT includes back-barrier layer 110 over the channel layer 108.

Returning to FIG. 3, in operation 350 an active layer is formed over the back barrier layer. In some embodiments, the active layer includes AlN, AlₓGa₁₋ₓN, combinations thereof or other suitable materials. In some embodiments, x ranges from about 0.1 to about 0.3. In some embodiments, the active layer is formed by performing an epitaxial process. In some embodiments, the epitaxial process includes a MOCVD process, a MBE process, a HVPE process or another suitable epitaxial process. In some embodiments, the active layer has a thickness ranging from about 10 nm to about 40 nm. In some embodiments where the active layer includes both AlN and AlₓGa₁₋ₓN, the AlN layer has a thickness ranging from about 0.5 nm to about 1.5 nm and the AlₓGa₁₋ₓN layer has a thickness ranging from about 10 nm to about 40 nm. In some embodiments, the active layer is formed at a temperature ranging from about 1000° C. to about 1200° C.

FIG. 4D is a cross-sectional view of a HEMT following operation 350 in accordance with one or more embodiments. The HEMT includes active layer 112 over the back barrier layer 110. 2-DEG 114 is formed in the channel layer 108 due to the band gap discontinuity between active layer 112 and the back barrier layer 110 and the channel layer 108.

Returning to FIG. 3, in operation 360 electrodes, such as a drain electrode, a source electrode, and a gate electrode, are formed on the active layer. In some embodiments, the drain electrode and the source electrode are formed over or partially buried in the channel layer, and the gate electrode is formed over the active layer. In some embodiments, a patterned mask layer (i.e., a photoresistive layer) is formed on the upper surface of the active layer, and an etching process is performed to remove a portion of the active layer to form openings partially exposing an upper surface of the channel layer. A metal layer is then deposited over the patterned active layer and fills the openings and contacts the channel layer. Another patterned photoresist layer is formed over the metal layer, and the metal layer is etched to form the source or drain electrodes over the openings and the gate electrode over the upper surface of the active layer. In some embodiments, the metal layer for forming the electrodes includes one or more conductive materials. In some embodiments, the electrodes include one or more layers of conductive materials. In at least one embodiment, the electrodes include at least one barrier layer contacting the channel layer and/or the active layer.

Following operation 360, the HEMT has a similar structure to HEMT 100.

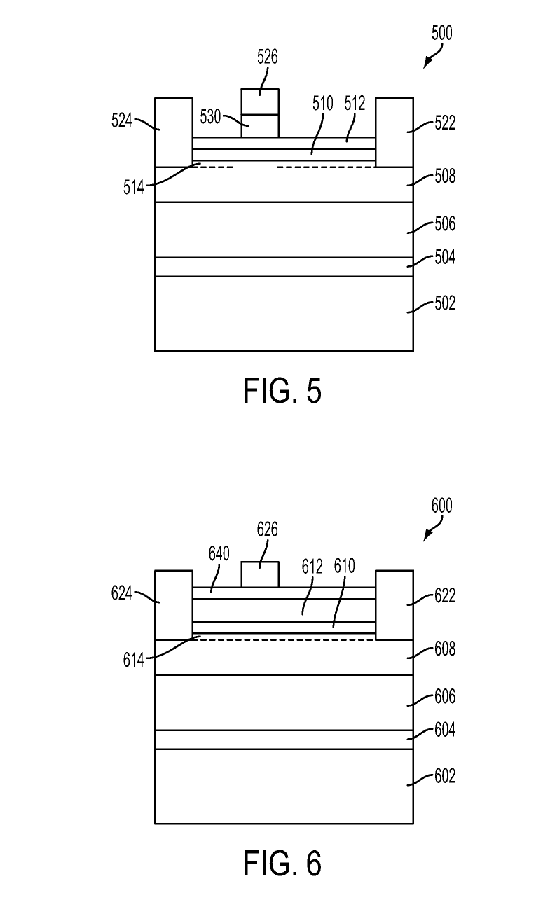

FIG. 5 is a cross-sectional view of an enhanced HEMT (E-HEMT) 500 in accordance with one or more embodiments. E-HEMT 600 is similar to HEMT 100. Similar elements have a same reference number as HEMT 100 increased by 400. In comparison with HEMT 100, E-HEMT 500 includes a semiconductor material 530 between gate electrode 526 and active layer 512. In some embodiments, semiconductor material 530 is a group III-V semiconductor material such as GaN, AlGaN, InGaN, or another suitable group III-V semiconductor material. In some embodiments, semiconductor material 530 is doped with p-type or n-type dopants. In some embodiments, the p-type dopants include carbon, iron, magnesium, zinc or other suitable p-type dopants. In some embodiments, the n-type dopants include silicon, oxygen or other suitable n-type dopants. In comparison with HEMT 100, E-HEMT 500 is normally non-conductive between electrodes 522 and 524. As a positive voltage is applied to gate electrode 526, E-HEMT 500 provides an increased conductivity between electrodes 522 and 524.

FIG. 6 is a cross-sectional view of a depletion metal-insulator-semiconductor field-effect transistor (D-MISFET) 600 in accordance with one or more embodiments. D-MISFET 600 is similar to HEMT 100. Similar elements have a same reference number as HEMT 100 increased by 500. In comparison with HEMT 100, D-MISFET 600 includes a dielectric layer 640 between gate electrode 626 and active layer 612. In some embodiments, dielectric layer 640 includes silicon dioxide. In some embodiments, dielectric layer 640 includes a high-k dielectric layer having a dielectric constant greater than a dielectric constant of silicon dioxide. Similar HEMT 100, D-MISFET 600 is normally conductive between electrodes 622 and 624. As a positive voltage is applied to gate electrode 626, D-MISFET 600 provides a decreased conductivity between electrodes 622 and 624.

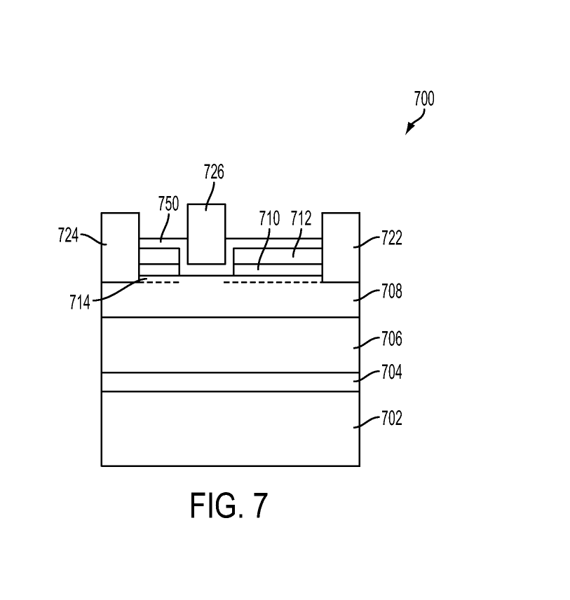

FIG. 7 is a cross-sectional view of an enhanced metal-insulator-semiconductor field-effect transistor (E-MISFET) 700 in accordance with one or more embodiments. E-MISFET 700 is similar to HEMT 100. Similar elements have a same reference number as HEMT 100 increased by 600. In comparison with HEMT 100, E-MISFET 700 includes a dielectric layer 750 between gate electrode 726 and channel layer 708. Dielectric layer 750 also separates gate electrode 726 and active layer 712. In some embodiments, dielectric layer 750 includes silicon dioxide. In some embodiments, dielectric layer 750 includes a high-k dielectric layer having a dielectric constant greater than a dielectric constant of silicon dioxide. In comparison with HEMT 100, E-MISFET 700 is normally non-conductive between electrodes 722 and 724. As a positive voltage is applied to gate electrode 726, E-MISFET 700 provides an increased conductivity between electrodes 722 and 724.

One aspect of this description relates to a transistor. The transistor includes a substrate, a channel layer over the substrate, a back-barrier layer over the channel layer, and an active layer over the back-barrier layer. The back-barrier layer has a band gap discontinuity with the channel layer. The band gap of the active layer is less than the band gap of the back-barrier layer. A two dimensional electron gas (2-DEG) is formed in the channel layer adjacent an interface between the channel layer and the back-barrier layer.

Another aspect of this description relates to a transistor. The transistor includes a substrate, a gallium nitride (GaN) channel layer over the substrate, a back-barrier layer over the GaN channel layer, and an active layer over the back-barrier layer. The back-barrier layer having a band gap discontinuity with the GaN channel layer, and a thickness of the first back-barrier layer ranges from about 1 angstrom (Å) to about 10 Å. The back-barrier layer has a band gap greater than that of the active layer.

Still another aspect of this description relates to a method of making a transistor. The method includes forming a channel layer over a substrate. A back-barrier layer is formed over the channel layer, and the back-barrier layer having a band gap discontinuity with the channel layer. An active layer is formed over the back-barrier layer, and the back-barrier layer has a band gap greater than that of the active layer.

It will be readily seen by one of ordinary skill in the art that the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. A transistor comprising:
a substrate;
a channel layer over the substrate;
a back-barrier layer over the channel layer, the back-barrier layer having a band gap discontinuity with the channel layer;
an active layer over the back-barrier layer, a band gap of the active layer being less than the band gap of the back-barrier layer;
a two dimensional electron gas (2-DEG) in the channel layer adjacent an interface between the channel layer and the back-barrier layer; and
a source electrode and a drain electrode over the channel layer, wherein a portion of at least one of the source electrode or the drain electrode is embedded in the channel layer.

2. The transistor of claim 1, wherein the back-barrier layer comprises aluminum nitride (AlN).

3. The transistor of claim 1, wherein a band gap of the back-barrier layer is at least 0.5 electron volt (eV) greater than a band gap of the active layer.

4. The transistor of claim 1, wherein a band gap of the back-barrier layer is about 1.8 eV greater than a band gap of the active layer.

5. The transistor of claim 1, further comprising a nucleation layer between the substrate and the channel layer.

6. The transistor of claim 5, wherein the nucleation layer comprises:
a first seed layer having a first lattice structure; and
a second seed layer on the first seed layer, the second seed layer having a second lattice structure different from the first lattice structure.

7. The transistor of claim 1, further comprising a buffer layer between the substrate and the channel layer.

8. The transistor of claim 7, wherein the buffer layer comprises a graded layer on the second seed layer, the graded layer having a multiple lattice structure.

9. The transistor of claim 1, further comprising:
a first electrode over the channel layer;
a second electrode over the channel layer; and
a gate electrode between the first electrode and the second electrode, the gate electrode being configured to control a conductivity of the 2-DEG between the first electrode and the second electrode.

10. The transistor of claim 9, wherein the gate electrode is over the active layer, and the transistor is configured to be normally conductive.

11. The transistor of claim 9, further comprising a semiconductor material on the active layer between the first electrode and the second electrode, wherein the gate electrode is on the semiconductor material and the transistor is configured to be normally non-conductive.

12. The transistor of claim 9, further comprising a dielectric layer on the active layer between the first electrode and the second electrode, wherein the gate electrode is over the dielectric layer, and the transistor is configured to be normally conductive.

13. The transistor of claim 9, further comprising:
an opening in the active layer between the first electrode and the second electrode;
a dielectric layer on the active layer and lining the opening, wherein the gate electrode is in the opening surrounded by the dielectric layer, and the transistor is configured to be normally non-conductive.

14. A transistor comprising:
a substrate;
a gallium nitride (GaN) channel layer over the substrate;
a back-barrier layer over the GaN channel layer, the back-barrier layer having a band gap discontinuity with the GaN channel layer, and a thickness of the first back-barrier layer ranging from about 1 angstrom (Å) to about 10 Å;
an active layer over the back-barrier layer, the back-barrier layer having a band gap greater than a band gap of the active layer; and
a source electrode and a drain electrode over the channel layer, wherein a portion of at least one of the source electrode or the drain electrode is embedded in the channel layer.

15. The transistor of claim 14, wherein the active layer comprises aluminum gallium nitride (AlGaN), the first back-barrier layer comprises aluminum nitride (AlN), and the thickness of the back-barrier layer ranges from about 1 Å to about 5 Å.

16. The transistor of claim 14, wherein the back-barrier layer has the band gap at least 0.5 electron volt (eV) greater than that of the active layer.

17. A method of making a transistor, the method comprising:
forming a channel layer over a substrate;
forming a back-barrier layer over the channel layer, the back-barrier layer having a band gap discontinuity with the channel layer;
forming an active layer over the back-barrier layer, the back-barrier layer having a band gap greater than a band gap of the active layer;
forming a source electrode and a drain electrode over the channel layer, wherein a portion of at least one of the source electrode or the drain electrode is embedded in the channel layer.

18. The method of claim 17, wherein the forming the back-barrier layer comprises forming an aluminum nitride (AlN) layer having a thickness ranging from about 1 angstrom (Å) to about 10 Å.

19. The method of claim 17, wherein the forming the active layer comprise forming an aluminum gallium nitride (AlGaN) layer, and the back-barrier layer comprises forming an aluminum nitride (AlN) layer having a thickness ranging from about 1 Å to about 5 Å.

20. The method of claim 17, wherein the forming the back-barrier layer and the forming the active layer are performed to cause a band gap of the back-barrier layer is at least 0.5 electron volt (eV) greater than the band gap of the active layer.
